(19) United States
(12) Patent Application Publication
(10) Pub. No.: US 2023/0317811 A1
(43) Pub. Date: Oct. 5, 2023

(54) SEMICONDUCTOR DEVICES

(71) Applicant: SAMSUNG ELECTRONICS CO., LTD., Suwon-si (KR)

(72) Inventors: Jinhong PARK, Seoul (KR); Jiwan KOO, Suwon-si (KR); Sahwan HONG, Suwon-si (KR); Juncheol KANG, Suwon-si (KR); Seunghwan SEO, Suwon-si (KR); Hogeun AHN, Suwon-si (KR); Jaewoong CHOI, Suwon-si (KR); Bongjin KUH, Suwon-si (KR)

(73) Assignee: SAMSUNG ELECTRONICS CO., LTD., Suwon-si (KR)

(21) Appl. No.: 17/989,435

(22) Filed: Nov. 17, 2022

(30) Foreign Application Priority Data
Mar. 30, 2022 (KR) 10-2022-0039267

(51) Int. Cl. H01L 29/45; H01L 29/24; H01L 29/76; H01L 21/02; H01L 29/40; H01L 29/66

(52) U.S. Cl. CPC H01L 29/45; H01L 29/24; H01L 29/7606; H01L 21/02568; H01L 29/401; H01L 29/66969

(57) ABSTRACT

A semiconductor device includes a channel on a substrate, the channel including a two-dimensional (2D) material, a gate insulating layer on a portion of the channel, a gate electrode on the gate insulating layer, first and second contact patterns on respective portions of the channel, the first and second contact patterns including a carbide of a transition metal, and first and second source/drain electrodes on the first and second contact patterns, respectively, and the first and second source/drain electrodes including a metal.

### CROSS-REFERENCE TO RELATED APPLICATION

This application is based on and claims priority under 35 USC § 119 to Korean Patent Application No. 10-2022-0039267, filed on Mar. 20, 2022 in the Korean Intellectual Property Office, the contents of which are incorporated by reference herein in their entirety.

### BACKGROUND

### 1 Field

Example embodiments relate to a semiconductor device. More particularly, example embodiments relate to a transistor.

### 2. Description of Related Art

A channel including silicon may be used in a semiconductor device, however, as the size of the semiconductor device decreases, the electrical characteristics of the channel including silicon reach a limit. Thus, a channel including a two-dimensional (2D) material having higher charge mobility than silicon has been developed. However, the 2D material has a high contact resistance with other structures.

### SUMMARY

Example embodiments provide a semiconductor device having improved characteristics.

In accordance with an aspect of the disclosure, a semiconductor device includes a channel on a substrate, the channel including a two-dimensional (2D) material; a gate insulating layer on a portion of the channel; a gate electrode on the gate insulating layer; a first contact pattern on a first portion of the channel and a second contact pattern on a second portion of the channel, the first contact pattern and the second contact pattern including a carbide of a transition metal; and a first source/drain electrode on the first contact pattern and a second source/drain electrode on the second contact pattern, the first source/drain electrode and the second source/drain electrode including a metal.

In accordance with an aspect of the disclosure, a semiconductor device includes a channel on a substrate, the channel including a 2-dimensional material; a gate insulating layer on a portion of the channel; a gate electrode on the gate insulating layer; a first contact pattern on a first portion of the channel and a second contact pattern on a second portion of the channel, the first contact pattern and the second contact pattern including a carbide of a transition metal, a nitride of a transition metal or a carbonitride of a transition metal; and a first source/drain electrode on the first contact pattern and a second source/drain electrode on the second contact pattern, the first source/drain electrode and the second source/drain electrode including a metal.

In accordance with an aspect of the disclosure, a semiconductor device includes an insulating layer on a substrate; a channel on the insulating layer, the channel including a 2D material; a first contact pattern on a first edge portion of the channel and a second contact pattern on a second edge portion of the channel, the first contact pattern and the second contact pattern including a carbide of a transition metal; a first source/drain electrode on the first contact pattern and a second source/drain electrode on the second contact pattern, the first source/drain electrode and the second source/drain electrode including a metal; a gate insulating layer on a central upper surface of the channel, on sidewalls of each of the first contact pattern and the second contact pattern, on sidewalls of each of the first source/drain electrode and the second source/drain electrode, and on an upper surface of each of the first source/drain electrode and the second source/drain electrode; a gate electrode on a portion of the gate insulating layer that is on the central upper surface of the channel, wherein a lower surface and a sidewall of the gate electrode are covered by the gate insulating layer; a first contact plug contacting an upper surface of the gate electrode; a second contact plug extending through the gate insulating layer and contacting an upper surface of the first source/drain electrode; and a third contact plug extending through the gate insulating layer and contacting an upper surface of the second source/drain electrode.

The semiconductor device in accordance with example embodiments may include the first and second contact patterns containing Mxene, which is a metallic 2D material and may reduce the contact resistance between the channel containing a semiconducting 2D material having a high charge mobility and each of the first and second source/drain electrodes including a metal, so as to have enhanced electric characteristics.

### BRIEF DESCRIPTION OF DRAWINGS

FIG. 1 is a cross-sectional view illustrating a semiconductor device according to an embodiment.

FIGS. 2 and 3 are graphs illustrating drain currents and total resistances of channels including rhenium disulfide (ReS₂), which is a semiconducting 2D material, and rhenium carbide (Re₂C), which is a metallic 2D material, respectively, and FIG. 4 is a graph illustrating contact resistivities between the channels and electrodes including a metal.

FIGS. 5 to 7 are cross-sectional views illustrating a method of manufacturing a semiconductor device according to an embodiment.

FIGS. 8 and 9 are cross-sectional views illustrating a method of manufacturing a semiconductor device according to an embodiment.

### DETAILED DESCRIPTION

Example embodiments will be described in detail with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

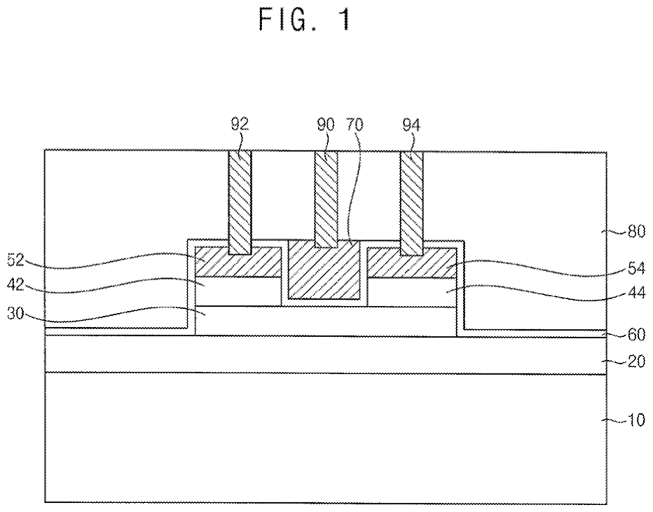

FIG. 1 is a cross-sectional view illustrating a semiconductor device in accordance with example embodiments.

Referring to FIG. 1, the semiconductor device may include an insulating layer 20, a channel 30, a first contact pattern 42 and a second contact pattern 44, a first source/drain electrode 52 and a second source/drain electrode 54, a gate insulating layer 60, a gate electrode 70, an insulating interlayer 80, first contact plug 90, second contact plug 92, and third contact plug 94 on a first substrate 10. The gate electrode 70, the gate insulating layer 60, the channel 30, the first and second contact patterns 42 and 44, and the first and second source/drain electrodes 52 and 54 may form a transistor.

The first substrate 10 may include, for example, a semiconductor material such as silicon, germanium, or silicon-germanium. The insulating layer 20 may include, for example, an insulating material such as an oxide or a nitride. Alternatively, the semiconductor device may include only an insulating substrate including an insulating material without the first substrate 10.

The channel 30 may be formed on the insulating layer 20. In example embodiments, the channel 30 may include a semiconducting two-dimensional (2D) material. The channel 30 may include a single layer, or may have a multi-layered structure including a plurality of single layers stacked in a vertical direction substantially perpendicular to an upper surface of the first substrate 10.

In an example embodiment, the 2D material may include a transition metal dichalcogenide (TMD) containing a transition metal and a chalcogen element, which may be represented by a chemical formula MX₂ (M: transition metal, X: chalcogen element). The transition metal may include, for example, molybdenum (Mo), tungsten (W), rhenium (Re), technetium (Tc), niobium (Nb), tantalum (Ta), hafnium (Hf), zirconium (Zr), osmium (Os), ruthenium (Ru), iridium (Ir), rhodium (Rh), platinum (Pt), palladium (Pd), Yittrium (Y), Lanthanum (La), Lutetium (Lu), scandium (Sc), titanium (Ti), vanadium (V), chromium (Cr), Manganese (Mn), iron (Fe), cobalt (Co), nickel (Ni), or the like, and the chalcogen element may include, for example, sulfur (S), selenium (Se), tellurium (Te), or the like. Thus, the TMD may include, for example, rhenium disulfide (ReS₂), molybdenum disulfide (MoS₂), tungsten disulfide (WS₂), rhenium diselenide (ReSe₂), molybdenum diselenide (MoSe₂), tungsten diselenide (WSe₂), or the like.

The first and second contact patterns 42 and 44 may be formed on opposite edge upper surfaces, respectively, of the channel 30.

Each of the first and second contact patterns 42 and 44 may include a metallic 2D material. In example embodiments, each of the first and second contact patterns 42 and 44 may include Mxene, that is, a carbide, a nitride or a carbonitride of a transition metal. For example, each of the first and second contact patterns 42 and 44 may include, e.g., rhenium carbide (ReₓC, x is one or two), rhenium nitride (ReₓN, x is one or two), or rhenium carbonitride (ReₓCN, x is one or two).

In example embodiments, the transition metal included in the Mxene may be substantially the same as that of the channel 30. Alternatively, the transition metal included in the Mxene may be different from that of the channel 30.

The first and second source/drain electrodes 52 and 54 may be formed on the first and second contact patterns 42 and 44, respectively. Each of the first and second source/drain electrodes 52 and 54 may include, e.g., a metal, a metal nitride, a metal silicide, etc.

The gate insulating layer 60 may be formed on a central upper surface of the channel 30 not covered by the first and second source/drain electrodes 52 and 54, on sidewalls of the first and second contact patterns 42 and 44, and on sidewalls and upper surfaces of the first and second source/drain electrodes 52 and 54, and may also be formed on an upper surface of the insulating layer 20. The gate insulating layer 60 may include an oxide, e.g., silicon oxide, a metal oxide, or the like.

The gate electrode 70 may be formed on a portion of the gate insulating layer 60 that is on the central upper surface of the channel 30. A lower surface and sidewalls of the gate electrode 70 may be covered by the gate insulating layer 60. In other words, the gate insulating layer 60 may be formed between the gate electrode 70 and the first and second contact patterns 42 and 44, and may also be formed between the gate electrode 70 and the first and second source/drain electrodes 52 and 54. The gate electrode 70 may include, e.g., a metal, a metal nitride, a metal silicide, doped polysilicon, etc.

The insulating interlayer 80 may be formed on the insulating layer 20, and may cover the gate insulating layer 60 and the gate electrode 70. The insulating interlayer 80 may include an oxide, e.g., silicon oxide, a nitride, e.g., silicon nitride, a low-k dielectric material, or the like.

The first contact plug 90 may extend through the insulating interlayer 80 to contact an upper surface of the gate electrode 70. The second and third contact plugs 92 and 94 may extend through the insulating interlayer 80 and the gate insulating layer 60 to contact upper surfaces of the first and second source/drain electrodes 52 and 54, respectively. The first to third contact plugs 92, 94 and 96 may include, e.g., a metal, a metal nitride, a metal silicide, or the like.

The semiconductor device may include the first and second contact patterns 42 and 44 between the channel 30 including a semiconducting 2D material and the first and second source/drain electrodes 52 and 54, respectively, including a metal, and each of the first and second contact patterns 42 and 44 may include a metallic 2D material, e.g., Mxene. Generally, the channel 30 including a semiconducting 2D material may have a charge mobility greater than that of a channel including silicon, however, a contact resistance between the channel and each of the first and second source/drain electrodes 52 and 54 including a metal may be high.

Accordingly, in example embodiments, the first and second contact patterns 42 and 44 including a metallic 2D material may be formed between the channel 30 and the first and second source/drain electrodes 52 and 54, and thus the contact resistance between the channel 30 and each of the first and second source/drain electrodes 52 and 54 may decrease.

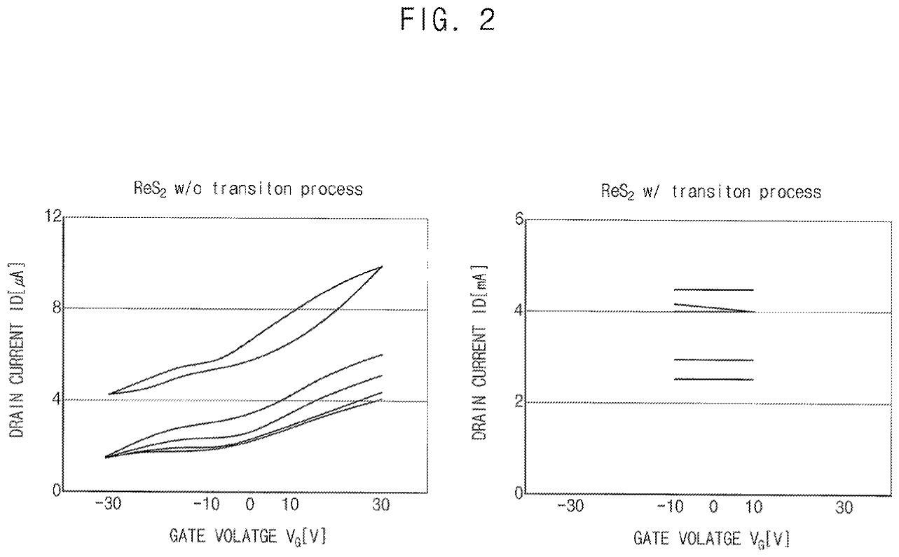

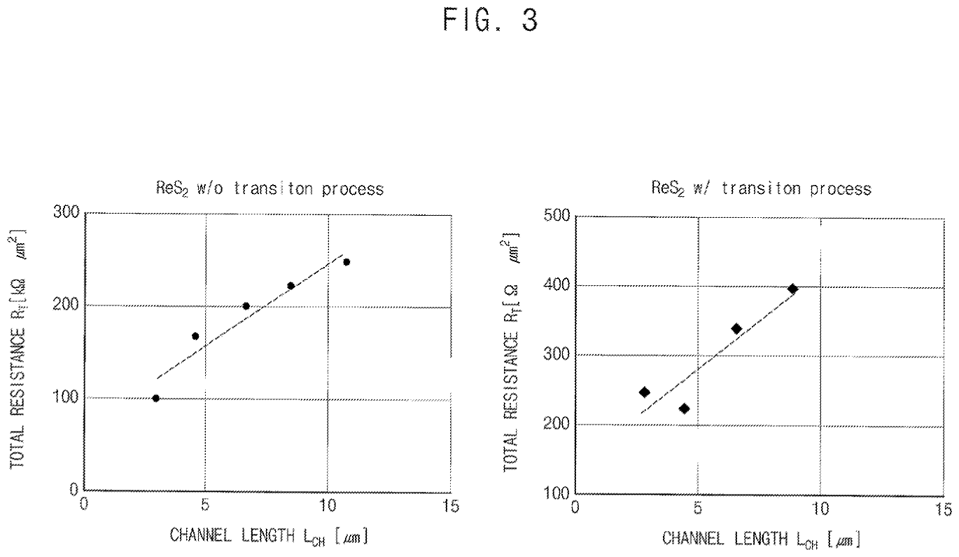

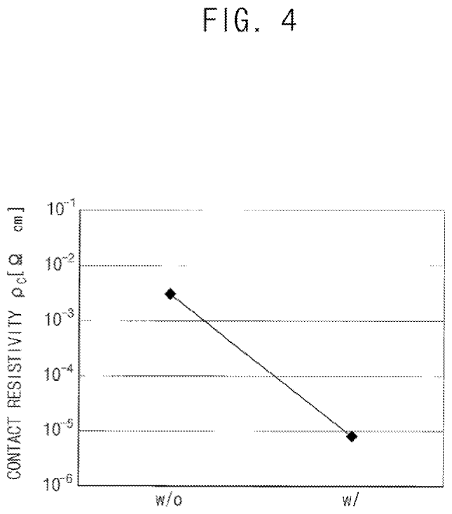

FIGS. 2 and 3 are graphs illustrating drain currents and total resistances of channels including rhenium disulfide (ReS₂), which is a semiconducting 2D material, and rhenium carbide (Re₂C), which is a metallic 2D material, respectively, and FIG. 4 is a graph illustrating contact resistivities between the channels and electrodes including a metal.

As illustrated below, a channel including rhenium carbide (Re₂C) may be formed by replacing sulfur (S) included in rhenium disulfide (ReS₂) with carbon (C), and thus a phase transition of the channel may occur from a semiconducting phase to a metallic phase.

Referring to FIG. 2, a drain current ID of a channel including rhenium carbide (Re₂C) (for example, the graph labeled “ReS₂ w/transition process” showing drain current on a scale of mA), which is a metallic 2D material, may have a value equal to or greater than about 100 times a drain current ID of a channel including rhenium disulfide (ReS₂) (for example, the graph labeled “ReS₂ w/o transition process” showing drain current on a scale of μA), which is a semiconducting 2D material.

Referring to FIG. 3, a total resistance of a channel including rhenium carbide (Re₂C) (for example, the graph labeled “ReS₂ w/transition process” showing total resistance on a scale of Ω·μm²), which is a metallic 2D material, may be much less than a total resistance of a channel including rhenium disulfide (ReS₂) (for example, the graph labeled “ReS₂ w/o transition process” showing total resistance on a scale of kΩ·μm²), which is a semiconducting 2D material.

Thus, referring to FIG. 4, a contact resistivity (0.3 kΩμm) of a channel including rhenium carbide (Re₂C), which is a metallic 2D material, may have a value equal to or less than about 1/400 of a contact resistivity (134 kΩμm) of a channel including rhenium disulfide (ReS₂), which is a semiconducting 2D material.

The semiconductor device may include the first and second contact patterns 42 and 44 containing Mxene, which is a metallic 2D material, in order to reduce the contact resistance between the channel 30 containing a semiconducting 2D material having a high charge mobility and each of the first and second source/drain electrodes 52 and 54 including a metal, so as to have enhanced electric characteristics.

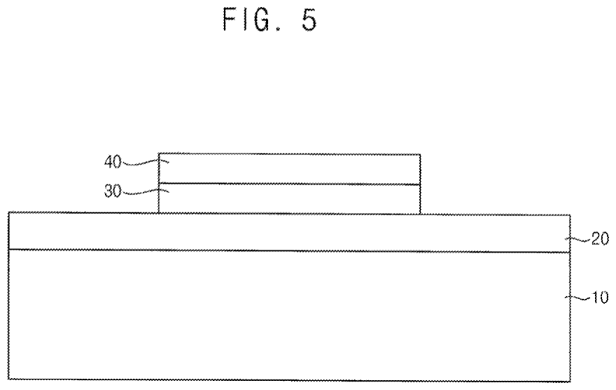

FIGS. 5 to 7 are cross-sectional views illustrating a method of manufacturing a semiconductor device in accordance with example embodiments.

Referring to FIG. 5, an insulating layer 20 may be formed on a first substrate 10, a channel 30 may be formed on the insulating layer 20, and a contact layer 40 may be formed on the channel 30.

In example embodiments, the channel 30 may be formed by, e.g., a chemical vapor deposition (CVD) process on the insulating layer 20, and may include a semiconducting 2D material. For example, the channel 30 may include a TMD, e.g., rhenium disulfide (ReS₂).

In example embodiments, the contact layer 40 may be formed by forming a preliminary contact layer including a semiconducting 2D material on a second substrate, placing the second substrate in a furnace, and providing a carbon source gas, e.g., methane (CH₄), hydrogen (H₂) and argon (Ar) into the furnace and heating the furnace. In an example embodiment, methane, hydrogen and argon may be provided into the furnace by flow rates of about 100 sccm, 5 sccm and 100 sccm, respectively, and the furnace may be heated to a temperature of about 730° C.

In an example embodiment, a copper foil may be disposed on the second substrate having the preliminary contact layer thereon, and may serve as a catalyst for converting methane (CH₄) into CH₃.

Thus, sulfur (S) included in rhenium disulfide (ReS₂) may be replaced with carbon (C) by CH₃ converted from methane (CH₄), and the preliminary contact layer may be converted into a contact layer 40 including Mxene, which is a metallic 2D material. That is, a phase transition from the preliminary contact layer including a semiconducting 2D material to the contact layer 40 including a metallic 2D material may occur.

The contact layer 40 on the second substrate may then be transferred onto the channel 30 on the first substrate 10.

The preliminary contact layer may include a TMD substantially the same as or different from a TMD included in the channel 30. The preliminary contact layer may include a single layer, or may have a multi-layered structure including a plurality of single layers stacked in a vertical direction substantially perp to an upper surface of the second substrate.

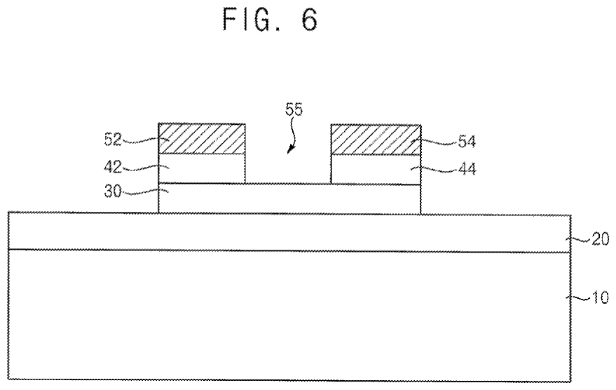

Referring to FIG. 6, a source/drain layer may be formed on the contact layer 40, an etching mask may be formed on the source/drain layer, and the source/drain layer and the contact layer 40 may be etched using the etching mask to form an opening 55 exposing an upper surface of the channel 30.

Thus, first and second contact patterns 42 and 44 may be formed on the channel 30, and first and second source/drain electrodes 52 and 54 may be formed on the first and second contact patterns 42 and 44, respectively.

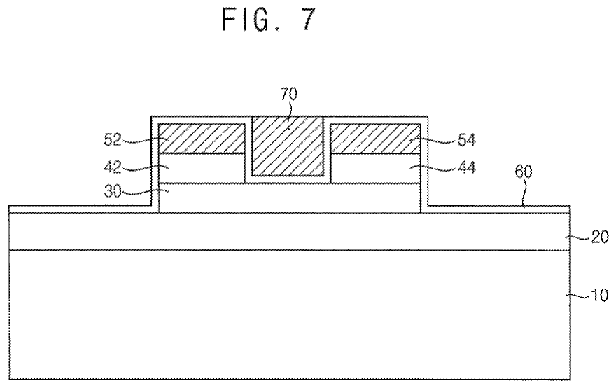

Referring to FIG. 7, a gate insulating layer 60 may be formed on an upper surface of the insulating layer 20, a sidewall of the channel 30, the upper surface of the channel 30 exposed by the opening 55, sidewalls of the first and second contact patterns 42 and 44, and sidewalls and upper surfaces of the first and second source/drain electrodes 52 and 54, and a gate electrode 70 may be formed on the gate insulating layer 60 to fill a remaining portion of the opening 55.

Referring to FIG. 1 again, an insulating interlayer 80 may be formed on the insulating layer 20 to cover the gate electrode 70 and the gate insulating layer 60, and a first contact plug 90 extending through the insulating interlayer 80 to contact an upper surface of the gate electrode 70, and second and third contact plugs 92 and 94 extending through the insulating interlayer 80 and the gate insulating layer 60 to contact upper surfaces of the first and second source/drain electrodes 52 and 54, respectively, may be formed.

By the above processes, the semiconductor device may be manufactured.

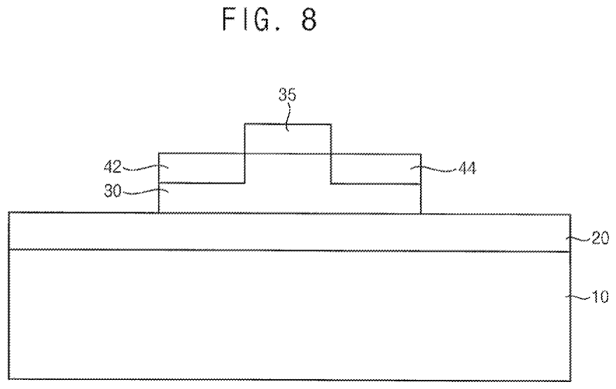

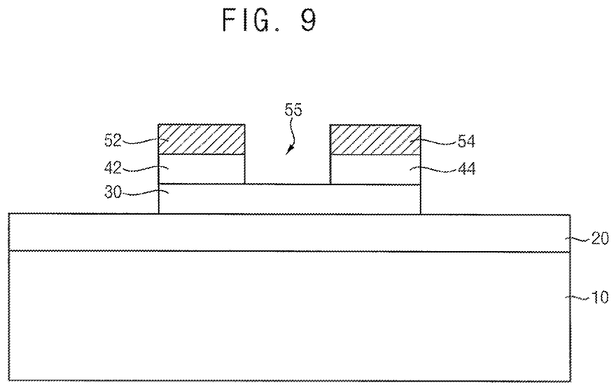

FIGS. 8 and 9 are cross-sectional views illustrating a method of manufacturing a semiconductor device in accordance with example embodiments. This method may include processes substantially the same as or similar to those illustrated with reference to FIGS. 5 to 7 and FIG. 1, and thus repeated explanations thereof are omitted herein.

Referring to FIG. 8, processes substantially the same as or similar to those illustrated with reference to FIG. 5 may be performed to form the insulating layer 20 and the channel 30 on the first substrate 10.

A mask 35 may be formed on the channel 30, the first substrate 10 having the above structures may be placed into a furnace, and processes substantially the same as or similar to those illustrated with reference to FIG. 5 may be performed so that a phase transition of upper portions of the channel 30 not covered by the mask 35 may occur. Thus, the first and second contact patterns 42 and 44 including a metallic 2D material, that is, Mxene may be formed at the upper portions, respectively, of the channel 30 including a semiconducting 2D material.

The mask 35 may be removed.

Referring to FIG. 9, processes substantially the same as or similar to those illustrated with reference to FIG. 6 may be performed.

Particularly, a source/drain layer may be formed on the channel 30 and the first and second contact patterns 42 and 44, an etching mask may be formed on the source/drain layer, and the source/drain layer, and an upper portion of the channel 30 between the first and second contact patterns 42 and 44 may be etched to form the opening 55 exposing an upper surface of a lower portion of the channel 30.

Thus, the first and second contact patterns 42 and 44 may be formed on the lower portion of the channel 30, and the first and second source/drain electrodes 52 and 54 may be formed on the first and second contact patterns 42 and 44, respectively.

Processes substantially the same as or similar to those illustrated with reference to FIG. 7 and FIG. 1 may be performed to complete the fabrication of the semiconductor device.

While example embodiments have been particularly shown and described, it will be understood by one of ordinary skill in the art that variations in form and detail may be made therein without departing from the spirit and scope of the claims.

What is claimed is:

1. A semiconductor device, comprising:
a channel on a substrate, the channel comprising a two-dimensional (2D) material;
a gate insulating layer on a portion of the channel;
a gate electrode on the gate insulating layer;
a first contact pattern on a first portion of the channel and a second contact pattern on a second portion of the channel, the first contact pattern and the second contact pattern comprising a carbide of a transition metal; and
a first source/drain electrode on the first contact pattern and a second source/drain electrode on the second contact pattern, the first source/drain electrode and the second source/drain electrode comprising a metal.

2. The semiconductor device of claim 1, wherein the transition metal comprises at least one from among molybdenum (Mo), tungsten (W), rhenium (Re), technetium (Tc), niobium (Nb), tantalum (Ta), hafnium (Hf), zirconium (Zr), titanium (Ti) and vanadium (V).

3. The semiconductor device of claim 2, wherein the carbide of the transition metal comprises rhenium carbide (ReₓC, x is one or two).

4. The semiconductor device of claim 1, wherein the channel comprises a transition metal dichalcogenide (TMD).

5. The semiconductor device of claim 4, wherein the channel, the first contact pattern, and the second contact pattern comprise substantially the same transition metal.

6. The semiconductor device of claim 1, further comprising:
a first contact plug on the gate electrode;
a second contact plug on the first source/drain electrode; and
a third contact plug on the second source/drain electrode.

7. The semiconductor device of claim 1, wherein the gate insulating layer is provided on a lower surface of the gate electrode and a sidewall of the gate electrode.

8. The semiconductor device of claim 1, wherein the gate insulating layer is provided on a sidewall of each of the first contact pattern and the second contact pattern, and
wherein the gate insulating layer is provided on a sidewall and an upper surface of each of the first source/drain electrode and the second source/drain electrode.

9. The semiconductor device of claim 1, further comprising an insulating layer between the substrate and the channel.

10. A semiconductor device, comprising:
a channel on a substrate, the channel comprising a two-dimensional (2D) material;
a gate insulating layer on a portion of the channel;
a gate electrode on the gate insulating layer;
a first contact pattern on a first portion of the channel and a second contact pattern on a second portion of the channel, the first contact pattern and the second contact pattern comprising a carbide of a transition metal, a nitride of a transition metal or a carbonitride of a transition metal; and
a first source/drain electrode on the first contact pattern and a second source/drain electrode on the second contact pattern, the first source/drain electrode and the second source/drain electrode comprising a metal.

11. The semiconductor device of claim 10, wherein the transition metal comprises at least one from among molybdenum (Mo), tungsten (W), rhenium (Re), technetium (Tc), niobium (Nb), tantalum (Ta), hafnium (Hf), zirconium (Zr), titanium (Ti) and vanadium (V).

12. The semiconductor device of claim 11, wherein the carbide of the transition metal comprises rhenium carbide (ReₓC, x is one or two).

13. The semiconductor device of claim 10, wherein the channel comprises a transition metal dichalcogenide (TMD).

14. The semiconductor device of claim 13, wherein the channel, the first contact pattern, and the second contact pattern comprise substantially the same transition metal.

15. The semiconductor device of claim 10, further comprising:
a first contact plug on the gate electrode;
a second contact plug on the first source/drain electrode; and
a third contact plug on the second source/drain electrode.

16. The semiconductor device of claim 10, wherein the gate insulating layer is provided on a lower surface of the gate electrode and a sidewall of the gate electrode.

17. The semiconductor device of claim 10, wherein the gate insulating layer is provided on a sidewall of each of the first contact pattern and the second contact pattern, and
wherein the gate insulating layer is provided on a sidewall and an upper surface of each of the first source/drain electrode and the second source/drain electrode.

18. The semiconductor device of claim 10, further comprising an insulating layer between the substrate and the channel.

19. A semiconductor device, comprising:
an insulating layer on a substrate;
a channel on the insulating layer, the channel comprising a two-dimensional (2D) material;
a first contact pattern on a first edge portion of the channel and a second contact pattern on a second edge portion of the channel, the first contact pattern and the second contact pattern comprising a carbide of a transition metal;
a first source/drain electrode on the first contact pattern and a second source/drain electrode on the second contact pattern, the first source/drain electrode and the second source/drain electrode comprising a metal;
a gate insulating layer on a central upper surface of the channel, on sidewalls of each of the first contact pattern and the second contact pattern, on sidewalls of each of the first source/drain electrode and the second source/drain electrode, and on an upper surface of each of the first source/drain electrode and the second source/drain electrode;
a gate electrode on a portion of the gate insulating layer that is on the central upper surface of the channel, wherein the gate insulating layer is provided on a lower surface and a sidewall of the gate electrode;
a first contact plug contacting an upper surface of the gate electrode;
a second contact plug extending through the gate insulating layer and contacting an upper surface of the first source/drain electrode; and
a third contact plug extending through the gate insulating layer and contacting an upper surface of the second source/drain electrode.

20. The semiconductor device of claim 19, wherein the channel comprises a transition metal dichalcogenide (TMD), and
wherein the channel, the first contact pattern, and the second contact pattern comprise substantially the same transition metal.
